(19) United States
(12) Patent Application Publication
(10) Pub. No.: US 2025/0255148 A1
(43) Pub. Date: Aug. 7, 2025

(54) TRANSPARENT DISPLAY APPARATUS

(71) Applicant: LG Display Co., Ltd., Seoul (KR)

(72) Inventors: JiHun SONG, Paju-si (KR); JongSung KIM, Paju-si (KR); Gyujae YOHN, Paju-si (KR)

(21) Appl. No.: 18/910,813

(22) Filed: Oct. 9, 2024

(30) Foreign Application Priority Data
Feb. 6, 2024 (KR) 10-2024-0018204

(51) Int. Cl. H10K 59/80; H10K 59/124

(52) U.S. Cl. CPC H10K 59/873; H10K 59/124

(57) ABSTRACT

A transparent display apparatus comprising: a substrate including a display area on which a plurality of pixels are disposed and a non-display area adjacent to the display area, the plurality of pixels each having a transmissive portion and a plurality of sub-pixels, and a plurality of dam areas disposed on the substrate, wherein each of the plurality of dam areas comprises: a first sub-dam surrounding a portion of the display area, and a second sub-dam disposed on the display area and connected to one side of the first sub-dam.

### CROSS-REFERENCE TO RELATED APPLICATIONS

This application claims the benefit of the Korean Patent Applications No. 10-2024-0018204 filed on Feb. 6, 2024, which are hereby incorporated by reference as if fully set forth herein.

### BACKGROUND

### Technical Field

The present disclosure relates to a transparent display apparatus.

### Description of the Related Art

With the advancement of the information age, the demand for a display apparatus for displaying an image has increased in various forms. Therefore, various types of display apparatuses such as a liquid crystal display (LCD) device, a plasma display panel (PDP) device, an organic light emitting display (OLED) device, micro LED display device and a quantum dot light emitting display (QLED) device have been recently used.

Recently, studies for a transparent display apparatus in which a user may view objects or background positioned at an opposite side by transmitting the display apparatus are actively ongoing.

The description provided in the background section should not be assumed to be prior art merely because it is mentioned in or associated with the background section. The background section may include information that describes one or more aspects of the subject technology.

### BRIEF SUMMARY

These transparent display apparatuses have the potential to be utilized in a wide variety of fields because they can be viewed both as an image and as a background, but due to the wide variety of applications and uses, they need to be manufactured in various types (or various sizes). However, when transparent display apparatuses are manufactured in multiple varieties (or different sizes), the number of processes increases, resulting in increasing manufacturing costs and production energy.

Therefore, the inventors of the present disclosure recognized the limitations mentioned above and other limitations associated with the related art, and conducted various experiments to implement a transparent display apparatus that substantially obviates one or more of the issues due to limitations and disadvantages of the related art.

An aspect of the present disclosure is to provide a transparent display apparatus that can be manufactured in various types (or various sizes).

Further, an aspect of the present disclosure is to provide a transparent display apparatus in which production energy can be reduced.

Further, an aspect of the present disclosure is to provide a transparent display apparatus that can be manufactured in various types (or various sizes) and still have reduced or prevented moisture permeation.

Further, an aspect of the present disclosure is to provide a transparent display apparatus that, even when manufactured in multiple varieties (or different sizes), can prevent or reduce dark spots from occurring due to out gassing from the dam.

Additional features and aspects of the disclosure are set forth in part in the description that follows and in part will become apparent from the description or may be learned by practice of the inventive concepts provided herein. Other features and aspects of the inventive concepts may be realized and attained by the structures pointed out in the present disclosure, or derivable therefrom, and the claims hereof as well as the appended drawings.

To achieve these and other aspects of the inventive concepts, as embodied and broadly described herein, a transparent display apparatus according to an embodiment of the present disclosure may include: a substrate including a display area on which a plurality of pixels are disposed and a non-display area adjacent to the display area, the plurality of pixels each having a transmissive portion and a plurality of sub-pixels; and a plurality of dam areas disposed on the substrate, wherein each of the plurality of dam areas comprises: a first sub-dam surrounding a portion of the display area, and a second sub-dam disposed on the display area and connected to one side of the first sub-dam.

A transparent display apparatus according to an embodiment of the present disclosure may include: a substrate including a display area on which a plurality of pixels are disposed and a non-display area adjacent to the display area, the plurality of pixels each having a transmissive portion and a plurality of sub-pixels; a plurality of dam areas surrounding the display area; and a buffer portion disposed inside an area surrounded by the dam areas.

The transparent display apparatus of the present disclosure includes the plurality of dam areas such that the display panel may be cut into various sizes.

Furthermore, the transparent display apparatus of the present disclosure may be manufactured in multiple varieties (or different sizes) without additional masking processes, which may result in lower production energy compared to transparent display apparatus produced in multiple varieties through different production processes.

Furthermore, the transparent display apparatus of the present disclosure is provided in such a way that the moisture permeation path in the cut portion is interrupted, so that moisture permeation may be reduced or prevented even when the product is manufactured in multiple varieties (or different sizes).

Further, the transparent display apparatus of the present disclosure provides the buffer portion between the first sub-dam and the second sub-dam adjacent to the cut portion, such that outgassing emitted from the first sub-dam and/or the second sub-dam may be stored in the buffer portion, thereby preventing or reducing the occurrence of dark spots.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which may be included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a transparent display apparatus according to an example embodiment of the present disclosure.

FIG. 2 is an enlarged top view of portion A shown in FIG. 1 according to an example embodiment of the present disclosure.

FIG. 3 is a schematic cross-sectional view of the line I-I′ shown in FIG. 2 according to an example embodiment of the present disclosure.

FIG. 4 is a schematic cross-sectional view of the line II-II′ shown in FIG. 2 according to an example embodiment of the present disclosure.

FIG. 5 is an enlarged plan view of portion B shown in FIG. 2 according to an example embodiment of the present disclosure.

FIG. 6 is a schematic cross-sectional view of the line III-III′ shown in FIG. 5 according to an example embodiment of the present disclosure.

FIG. 7 is a schematic plan view of a transparent display apparatus according to another example embodiment of the present disclosure.

FIG. 8 is a schematic cross-sectional view of lines IV-IV′ shown in FIG. 7 according to another example embodiment of the present disclosure.

FIG. 9 is a cross-sectional view of lines IV-IV′ shown in FIG. 7, illustrating a transparent display apparatus according to another example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure will be sufficiently thorough and complete to assist those skilled in the art to fully understand the scope of the present disclosure. Further, the claims are not limited by the present disclosure.

A shape, a size, a ratio, an angle, and a number disclosed in the drawings for describing various example embodiments of the present disclosure are merely given by way of example, and thus, the present disclosure is not limited to the illustrated details. Any implementation described herein as an “example” is not necessarily to be construed as preferred or advantageous over other implementations.

Like reference numerals refer to like elements throughout. In the following description, when the detailed description of the relevant known function or configuration is determined to unnecessarily obscure the important point of the present disclosure, the detailed description will be omitted or may be briefly provided.

In a case where ‘comprise,’ ‘have,’ ‘include’, “contain,” “constitute,” “make up of,” “formed of,” and the like, described in the present specification are used, another part may be added unless a more limiting term, such as ‘only˜’ is used. The terms of a singular form may include plural forms unless referred to the contrary.

In construing an element, the element is construed as including an error range or tolerance range although there is no explicit description of such an error or tolerance range.

In describing a position relationship, for example, when a position relation between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,”“below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In describing a temporal relationship, for example, when the temporal order is described as for example, “after,” “subsequent,” “next,” and “before,” a case which is not continuous may be included, unless a more limiting term, such as “just,” “immediate(ly),” or “direct(ly)” is used.

It will be understood that, although the terms “first,” “second,” “A,” “B,” “(a),” and “(b),” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure. Also, when an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, example embodiments of the present disclosure will be described in detail with reference to the accompanying drawings. Further, all the components of each transparent display apparatus according to all embodiments of the present disclosure are operatively coupled and configured.

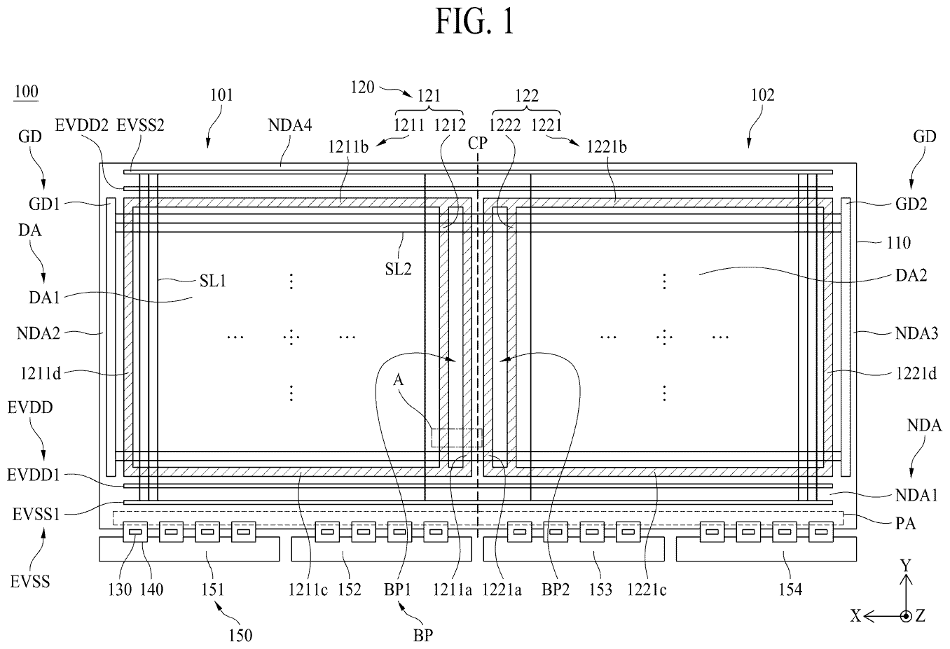

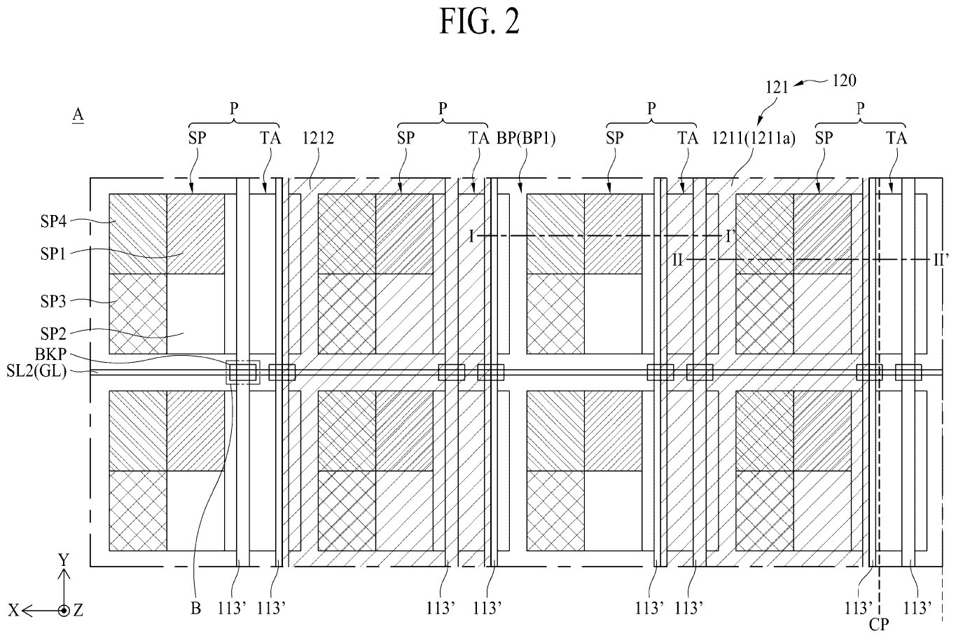

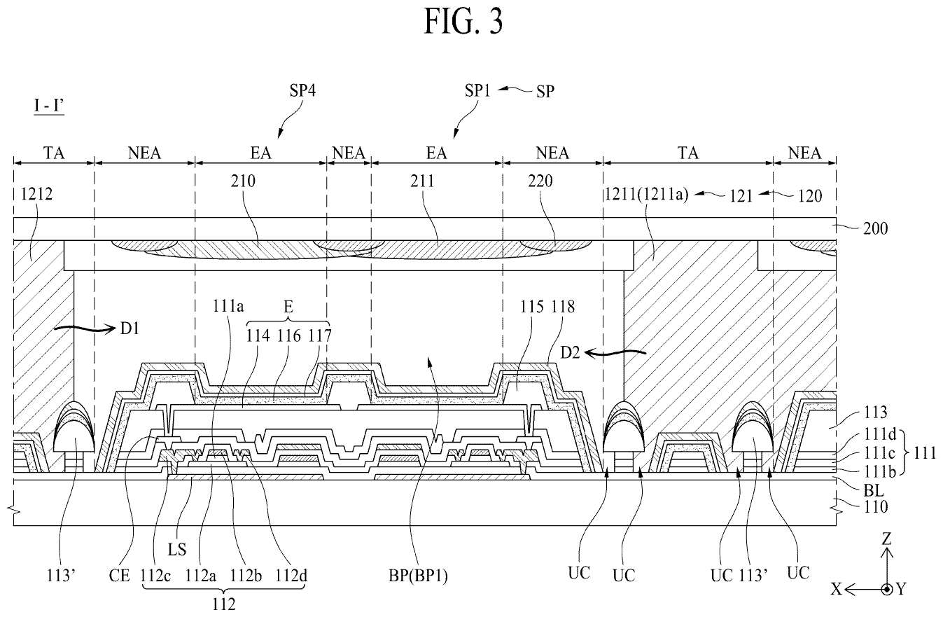

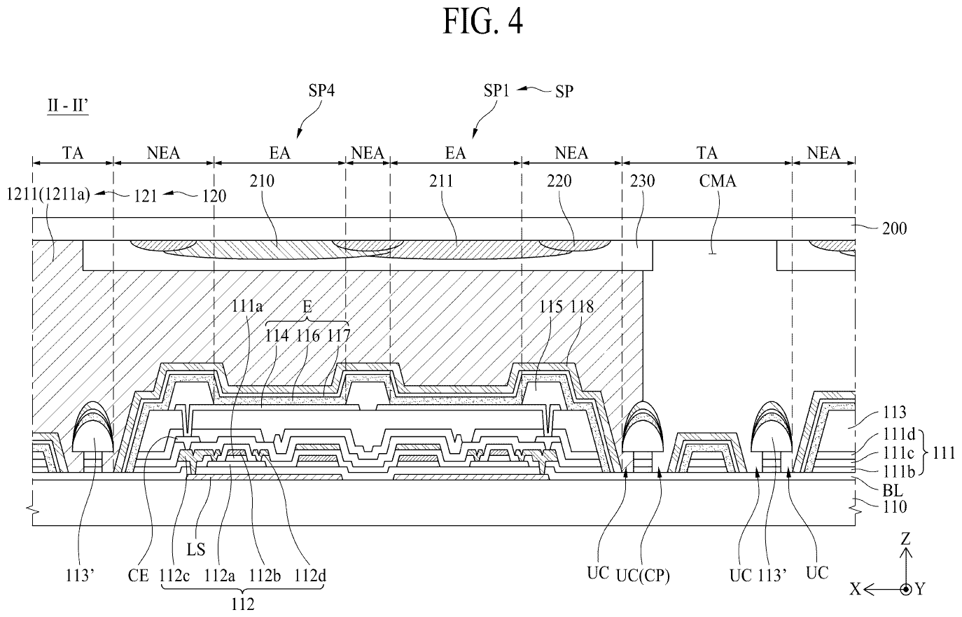

FIG. 1 is a schematic plan view of a transparent display apparatus according to an example embodiment an example embodiment of the present disclosure, FIG. 2 is an enlarged top view of portion A shown in FIG. 1, FIG. 3 is a schematic cross-sectional view of the line I-I′ shown in FIG. 2, and FIG. 4 is a schematic cross-sectional view of the line II-II′ shown in FIG. 2.

Hereinafter, a Y-axis direction indicates a direction in parallel to a first line SL1 (e.g., the data line) (e.g., a first direction), a X-axis direction indicates a direction in parallel to a second line SL2 (e.g., the gate line) (e.g., a second direction), and a Z-axis direction indicates a thickness direction of the transparent display apparatus 100 (e.g., a third direction).

Referring now to FIG. 1 to FIG. 4, a transparent display apparatus 100 according to an example embodiment of the present disclosure includes a substrate 110 having a display area DA and a non-display area NDA (or bezel area) and a plurality of dam areas 120. The plurality of dam areas 120 are provided on the substrate 110. The display area DA includes a plurality of pixels P having a transmissive portion TA and a plurality of sub-pixels SP, respectively, and the non-display area NDA is adjacent to (for example, at least partially surrounding) the display area DA. Each of the plurality of dam areas 120, according to one example, may be configured as a closed loop extending from the non-display area NDA (or bezel area) to the display area DA. Thus, a portion of each of the plurality of dam areas 120 may be disposed in the non-display area NDA and the other portion (or remaining portion) may be disposed in the display area DA.

Specifically, each of the plurality of dam areas 120 according to one example may include a first sub-dam 1211 that surrounds a portion of the display area DA, and a second sub-dam 1212 disposed on the display area DA and connected to a one side of the first sub-dam 1211. In one example, the second sub-dam 1212 may be disposed to be spaced apart from the one side of the first sub-dam 1211 inside an area surrounded by the first sub-dam 1211, and both ends of the second sub-dam 1212 may be connected to portions of the first sub-dam 1211 other than the one side of the first sub-dam 1211. Thus, the second sub-dam 1212 may be connected to the one side of the first sub-dam 1211. The plurality of dam areas 120 may include the first dam 121 provided in a left portion of the transparent display apparatus 100, and a second dam 122 adjacent to the first dam 121 and provided in a right portion of the transparent display apparatus 100. The first dam 121, according to one example, may include a first sub-dam 1211 and a second sub-dam 1212. The second dam 122, according to one example, may include a first sub-dam 1221 and a second sub-dam 1222.

On the other hand, each of the plurality of dam areas 120 being provided as a closed loop may mean that the display area DA is partially surrounded by the dam areas 120, as shown in FIG. 1. The display area DA according to one example may include a first display area DA1, and a second display area DA2 disposed adjacent to the first display area DA1. Thus, the display area DA may have a structure that is divided by a plurality of dam areas 120 having a closed structure. For example, as shown in FIG. 1, the transparent display apparatus 100 according to an example embodiment of the present disclosure may include two dam areas 120 (or first dam 121 and second dam 122), and may include two display areas DAs having the same or different areas (or sizes) divided by each dam area 120.

Thus, the transparent display apparatus 100 according to an example embodiment of the present disclosure may be divided into two transparent display apparatuses having the same or different areas (or sizes) when a cut is made between the two dam areas 120. For example, the transparent display apparatus 100 according to an example embodiment of the present disclosure may be divided into a first transparent display apparatus 101 having the first display area DA1, and a second transparent display apparatus 102 having the second display area DA2, which may have the same or different area (or size) as the first display area DA1. Thus, the transparent display apparatus 100 according to an example embodiment of the present disclosure may be manufactured in a variety of sizes (or different sizes) by being provided with a plurality of dam areas 120 such that the display panels may be cut into the same or different sizes. However, the transparent display apparatus 100 according to an example embodiment of the present disclosure may also be implemented as a single transparent display apparatus if it is not divided by a cutting device.

As shown in FIG. 1, a transparent display apparatus 100 according to an example embodiment of the present disclosure may be configured to include two dam areas 120, thus may be implemented as the first transparent display apparatus 101 having the first area, and the second transparent display apparatus 102 having the second area equal to or different from the first area. The display panel may include a substrate 110 and an opposing substrate 200 that is facing the substrate 110 and bonded to the substrate 110.

Accordingly, in the transparent display apparatus 100 according to an example embodiment of the present disclosure, production energy may be reduced compared to a transparent display apparatus produced in various types (or various sizes) through different production processes (or manufacturing processes).

Also, even if the transparent display apparatus 100 according to an example embodiment of the present disclosure is divided into the first and second transparent display apparatuses 101, 102, moisture permeation may be reduced or prevented because the plurality of the dam area 120 (or the first dam 121 or the second dam 122) covers the edges of each of the first and second transparent display apparatuses 101, 102 in a closed-loop structure (or closed structure). Thus, even though the transparent display apparatus 100 according to an example embodiment of the present disclosure is cut (or divided) into a plurality of transparent display apparatuses, the reliability of each of the plurality of transparent display apparatuses against moisture permeation may be improved.

In another aspect, the transparent display apparatus 100 according to an example embodiment of the present disclosure may include a buffer portion BP disposed inside an area surrounded by the dam area 120 (or the first dam 121 or the second dam 122). The buffer portion BP is a space for inducing outgassing contained within the dam area 120. The space of the buffer portion BP is a different space from the space in which the cut is made. For example, the buffer portion BP is a space where the outgassing emitted from the dam area is stored. Thus, the buffer portion BP may be expressed in terms of an outgassing storage area. The buffer portion BP may include a first buffer portion BPI disposed inside an area surrounded by the first dam 121, and a second buffer portion BP2 disposed inside an area surrounded by the second dam 122. In one example, the first buffer portion BPI may be disposed between the first sub-dam 1211 and the second sub-dam 1212. The second buffer portion BP2, according to one example, may be disposed between the first sub-dam 1221 and the second sub-dam 1222. The buffer portion BP may be a space where out gassing from the dam area 120 (or the first dam 121 or the second dam 122) is stored. Since the buffer portion BP is a space formed by the dam areas 120 disposed at the left portion and right portion of the light emission area EA with reference to FIG. 3, it may be expressed by the term buffer area.

In one example, the buffer portion BP may be a vacuum. By the buffer portion BP provided to be a vacuum, the out gassing contained in the dam area 120 (or the first dam 121 or the second dam 122) may be more easily induced into the buffer portion BP, which is a vacuum, rather than intruding into the light emitting element layer E (or organic light emitting layer) included in each of the plurality of pixels P (or a plurality of sub-pixels SP). If out gassing intrudes into the light emitting element layer E (or organic light emitting layer) included in each of the plurality of pixels P (or the plurality of sub pixels SP), the light emitting element layer E (or organic light emitting layer) may be damaged and the corresponding pixel P (or sub pixel SP) may not be driven and may be seen as a dark spot by the user.

However, the transparent display apparatus 100 according to an example embodiment of the present disclosure has the buffer portion BP between the first sub-dam 1211 (or the first sub-dam 1221) and the second sub-dam 1212 (or the second sub-dam 1222), therefore out gassing emitted from the first sub-dam 1211 (or the first sub-dam 1221) and/or the second sub-dam 1212 (or the second sub-dam 1222) may be released into the buffer portion BP, thus damage to the organic light emitting layer may be prevented or reduced, thereby preventing or reducing the occurrence of dark spots.

On the other hand, as shown in FIG. 3, the organic light emitting layer 116 in the light emission area EA is sealed by the cathode electrode 117 and an encapsulation layer 118 on the organic light emitting layer 116, thus the outgassing released in the buffer portion BP may not penetrate into the organic light emitting layer 116.

Hereinafter, with reference to FIGS. 1 to 4, a transparent display apparatus 100 according to an example embodiment of the present disclosure will be described in more detail.

Referring to FIG. 1, a transparent display apparatus 100 according to an example embodiment of the present disclosure may include a source drive integrated circuit (hereinafter IC) 130, a flexible film 140, and a plurality of circuit boards 150, and a display panel including a substrate 110 having the plurality of gate drivers GDs. Although not shown, the plurality of circuit boards 150 may be connected to a timing controller via cables.

The display panel may include a substrate 110 and an opposite substrate 200 (shown in FIG. 3).

The substrate 110 may include a thin film transistor, and may be a transistor array substrate, a lower substrate, a base substrate, or a first substrate. The substrate 110 may be a transparent glass substrate or a transparent plastic substrate. For example, the substrate 110 may be a transparent glass substrate. Hereinafter, the substrate 110 will be defined as a first substrate.

The opposing substrate 200 may be facing the first substrate 110 and bonded to the first substrate 110 via the first dam 121, the second dam 122, and a filling member (RF, shown in FIG. 6) that are included in the dam area 120. For example, the opposing substrate 200 may have a smaller size than the first substrate 110 and may be facing and bonded to a portion of the first substrate 110 except the pad portion. The opposing substrate 200 may be an upper substrate, a second substrate, or an envelope substrate. The opposing substrate 200 may be bonded to the first side of the first substrate 110 by a substrate bonding process mediated by an adhesive member. Hereinafter, the opposing substrate 200 is defined as the second substrate.

The dam area 120, according to one example, may include the first dam 121 and the second dam 122. Each of the first dam 121 and the second dam 122 may be disposed between the first substrate 110 and the second substrate 200. Accordingly, the first substrate 110 and the second substrate 200 may be facing and oppositely bonded to each other via the first dam 121 and the second dam 122. For example, each of the first dam 121 and the second dam 122 may include a thermosetting clear adhesive or a light-curable clear adhesive. Each of the first dam 121 and the second dam 122 may include an absorbent material (not shown) for absorbing external moisture or humidity that penetrates toward the display area DA.

The dam area 120, according to one example, may be disposed in the non-display area NDA and to extend from the non-display area NDA to the display area DA. As shown in FIG. 3, the dam area 120 may be disposed to fill a gap between the first substrate 110 and the second substrate 200. Accordingly, the dam area 120 (or the first dam 121 and the second dam 122) may prevent or reduce moisture or the like from penetrating through the gap between the first substrate 110 and the second substrate 200 towards the display area DA.

The filling member RF may be disposed adjacent to the dam area 120. The filling member RF may be disposed to fill a gap between the first substrate 110 and the second substrate 200, thereby supporting the first substrate 110 and the second substrate 200. Thus, the filling member RF may prevent or reduce the first substrate 110 and the second substrate 200 from being easily deformed by an external force.

On the other hand, the filling member RF or the dam area 120 may be disposed between an organic light-emitting layer 116 formed on the first substrate 110 and the second substrate 200 to prevent or reduce external moisture or humidity permeating through the second substrate 200 from reaching the organic light-emitting layer 116. In other words, each of the filling member RF and the dam area 120 may have a barrier function to prevent or reduce moisture permeation. Each of the filling member RF and the dam area 120 may further include an absorbent material to absorb water or moisture to increase the moisture barrier effect. For example, the absorbent material may be a getter.

On the other hand, the filling member RF may comprise a thermosetting transparent adhesive or a light-curable transparent adhesive. In this case, the filling member RF may be utilized to bond the first substrate 110 and the second substrate 200 together with the dam area 120. Thus, the bonding force of the first substrate 110 and the second substrate 200 may be further improved. Since each of the plurality of dam areas 120 partially surrounds the display area DA, the filling member RF may be disposed to be surrounded by the dam area 120. The dam area 120 may overlap the plurality of pixels P by being partially disposed in the display area DA.

The dam area 120 according to one example may comprise an opaque material but is not necessarily limited thereto and may comprise a transparent material. The filling member RF according to one example is disposed in the display area DA, so it may comprise a transparent material to improve the transmittance of the light emitted.

Referring again to FIG. 1, the gate driver GD supplies gate signals to the gate lines in accordance with the gate control signal input from the timing controller. When the source drive IC 130 is manufactured as a driving chip, the source drive IC 130 may be packaged in the flexible film 140 in a chip on film (COF) method or a chip on plastic (COP) method.

Pads, such as power pads, data pads, may be formed in the non-display area NDA of the display panel. Lines connecting the pads with the source drive IC 130 and lines connecting the pads with lines of the circuit board 150 may be formed in the flexible film 140. The flexible film 140 may be attached onto the pads by using an anisotropic conducting film, whereby the pads may be connected with the lines of the flexible film 140.

The first substrate 110 according to an example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel (or the first substrate 110).

The display area DA according to an example may include gate lines, data lines, pixel driving power lines, and a plurality of pixels P. Each of the plurality of pixels P may include a plurality of sub-pixels SP and the transmissive portion TA (shown in FIG. 2). The plurality of sub-pixels SP may be defined by the gate lines and the data lines. The transmissive portion TA is disposed adjacent to the plurality of sub-pixels SP. The transmissive portion TA is an area configured to allow light to transmit through the front and back sides of the display panel. Thus, a user positioned at the front side of the display panel can view an image, background, or the like positioned at the back side of the display panel through the transmissive portion TA.

Referring to FIG. 2, each of the plurality of sub-pixels SP may be defined as an area of the smallest unit in which actual light is emitted.

According to one example, at least four sub-pixels SP disposed adjacent to each other among the plurality of sub-pixels SP, and one transmissive portion TA comprise one unit pixel P. The one unit pixel may include a red pixel, a green pixel, a blue pixel, a white pixel, and the transmissive portion TA, but is not limited to. In one example, the one unit pixel may comprise at least one red pixel, at least one green pixel, at least one blue pixel, at least one white pixel, and at least one transmissive portion TA.

In another example, three sub-pixels SPs disposed adjacent to each other among the plurality of sub-pixels SPs, and one transmissive portion TA comprise one unit pixel. The one unit pixel may include, but is not limited to, at least one red pixel, at least one green pixel, at least one blue pixel, and one transmissive portion TA.

Each of the plurality of sub-pixels SPs may include a thin film transistor, and a light emitting portion connected to the thin film transistor. The light emitting portion may include a light emitting element layer (or the organic light emitting layer) interposed between the anode electrode (or first electrode) and the cathode electrode (or second electrode).

The light emitting element layers respectively disposed in the plurality of subpixels SP may individually emit light of their respective colors different from one another or commonly emit white light. According to an example, when the light emitting element layers of the plurality of subpixels SP commonly emit white light, each of the red subpixel, the green subpixel and the blue subpixel may include a color filter (or wavelength conversion member) for converting white light into light of its respective different color. In this case, the white subpixel according to an example may not include a color filter. In the transparent display apparatus 100 according to an example embodiment of the present disclosure, the red sub-pixel may be a first sub-pixel SP1, the white sub-pixel may be a second sub-pixel SP2, the green sub-pixel may be a third sub-pixel SP3, and the blue sub-pixel may be a fourth sub-pixel SP4.

Each of the subpixels SP supplies a predetermined current to the organic light emitting element in accordance with a data voltage of the data line when a gate signal is input from the gate line by using the thin film transistor. For this reason, the light emitting portion of each of the subpixels may emit light with a predetermined brightness in accordance with the predetermined current. A structure of each of the subpixels SP will be described later with reference to FIG. 3.

The non-display area NDA may be an area where an image is not displayed, and may be a peripheral circuit area, a signal supply area, a non-active area, or a bezel area. The non-display area NDA may be configured to be around the display area DA. For example, the non-display area NDA may be disposed to surround the display area DA.

The transparent display apparatus 100, according to an example embodiment of the present disclosure, may include the plurality of gate drivers GDs disposed on the non-display area NDA. As shown in FIG. 1, the plurality of gate driver GDs may be disposed in the first direction (Y-axis direction) in the non-display area NDA. The plurality of gate drivers GDs may be disposed in parallel to each other interposed the display area DA therebetween, but are not necessarily limited thereto.

Each of the plurality of gate drivers GDs supplies gate signals to the gate lines according to gate control signals input from the timing controller connected to the plurality of circuit boards 150. Each of the plurality of gate drivers GDs may be formed in a gate driver in panel GIP manner in the non-display area NDA on either outer side of the display area DA, as shown in FIG. 1. Alternatively, the plurality of gate drivers GD may be made of a driving chip, mounted on a flexible film, and attached to the non-display areas NDA on both outer sides of the display area DA of the display panel by a TAB (tape automated bonding) method. The gate driver GD according to one example may include a plurality of gate driver circuits (or GIP circuits) and a plurality of GIP wiring. The GIP wiring, in one example, may include a plurality of signal wiring and a plurality of power wiring.

The plurality of gate drivers GDs may be disposed separately on the left side of the display area DA, for example, the second non-display area NDA2, and on the right side of the display area DA, for example, the third non-display area NDA3. According to one example, a plurality of gate drivers GD may be connected to the plurality of pixels P and the plurality of wiring (or a plurality of second lines SL2) for supplying power and/or signals to each of the plurality of pixels P. As shown in FIG. 1, the transparent display apparatus 100 according to an example embodiment of the present disclosure may further include a plurality of first lines SL1 intersecting with the plurality of second lines SL2.

The plurality of second lines SL2 may extend long in a second direction (X-axis direction). Each of the plurality of second lines SL2 may include at least one gate line GL (or scan line GL). The second direction (X-axis direction) may refer to a direction in parallel to the gate line GL.

In the following, when the second line SL2 comprises a plurality of lines, one second line SL2 may refer to a group of signal lines comprising a plurality of lines. For example, when the second line SL2 includes two scan lines, one second line SL2 may refer to a group of signal lines comprising two scan lines.

The plurality of first lines SL1 may extend long in the first direction (Y-axis direction). The plurality of first lines SL1 may intersect with the plurality of second lines SL2. Each of the plurality of first lines SL1 may be connected to at least one of a plurality of pads, a pixel power shorting bar EVDD, and a common power shorting bar EVSS disposed in a first non-display area NDA1. The pixel power supply shooting bar EVDD and the common power supply shooting bar EVSS may be disposed in the first non-display area NDA1 disposed between the pad area PA and the display area DA with respect to the display area DA, and in a fourth non-display area NDA4 disposed to face the pad area PA. The first direction (X-axis direction) may be a direction in parallel to the data line.

The pixel-powered shooting bar EVDD may include a first pixel-powered shooting bar EVDD1 disposed in the first non-display area NDA1, and a second pixel-powered shooting bar EVDD2 disposed in the fourth non-display area NDA4. The first pixel power shorting bar EVDD1 and the second pixel power shorting bar EVDD2 may be disposed in parallel to the second direction (X-axis direction) with the display area DA interposed therebetween.

The common power supply shooting bar EVSS may include a first common power supply shooting bar EVSS1 disposed in the first non-display area NDA1, and a second common power supply shooting bar EVSS2 disposed in the fourth non-display area NDA4. The first common power supply shorting bar EVSS1 and the second common power supply shorting bar EVSS2 may be disposed in parallel to the second direction (X-axis direction) with the display area DA interposed therebetween. According to an example, the first common power supply shooting bar EVSS1 and the second common power supply shooting bar EVSS2 may be disposed closer to the edge of the first substrate 110 than the first pixel power supply shooting bar EVDD1 and the second pixel power supply shooting bar EVDD2

The plurality of first lines SL1 may include a pixel power line connected to the pixel power shorting bar EVDD and a common power line connected to the common power shorting bar EVSS. In an example embodiment, the plurality of first lines SL1 may further include a plurality of data lines and reference lines.

Hereinafter, when the first line SL1 includes a plurality of lines, one first line SL1 may refer to a signal line group consisting of a plurality of lines. For example, when the first line SL1 includes two data lines, the pixel power line, the common power line, and the reference line, one first line SL1 may refer to a group of signal lines comprising two data lines, the pixel power line, the common power line, and the reference line.

The pixels P are disposed to overlap with at least one of the first line SL1 and the second line SL2, and emit a predetermined light to display an image. The light emission area EA may correspond to an area in which the pixels P emit light. The light emission area EA according to one example may be disposed adjacent to the transmissive portion TA.

Referring to FIG. 2, each of the pixels P may include a first sub-pixel SP1, a second sub-pixel SP2, a third sub-pixel SP3, and a fourth sub-pixel SP4. The first sub-pixel SP1 may be configured to include a first light emission area EA emitting red light, the second sub-pixel SP2 may be configured to include a second light emission area emitting white light, the third sub-pixel SP3 may be configured to include a third light emission area emitting green light, and the fourth sub-pixel SP4 may be configured to include a fourth light emission area emitting blue light. In FIG. 2, the first to fourth sub-pixels SP1, SP2, SP3, SP4 included in the one pixel P may be configured in a 2×2 structure. For example, the first sub-pixel SP1 that emits red light, the second sub-pixel SP2 that emits white light, the third sub-pixel SP3 that emits green light, and the fourth sub-pixel SP4 that emits blue light may be provided in a 2×2 structure. Specifically, the fourth sub-pixel SP4 emitting blue light and the first sub-pixel SP1 emitting red light may be disposed adjacent to each other in the second direction (X-axis direction), and the third sub-pixel SP3 emitting green light and the second sub-pixel SP2 emitting white light may be disposed adjacent to each other in the second direction (X-axis direction). Here, the third sub-pixel SP3 and the second sub-pixel SP2 may be disposed below the fourth sub-pixel SP4 and the first sub-pixel SP1 in respect to FIG. 2, for example, adjacent in the first direction (Y-axis direction), respectively. Also, on the right side of the first sub-pixel SP1 and the second sub-pixel SP2, a transmissive portion TA may be disposed adjacent thereto. However, the arrangement structure of the first to fourth sub-pixels SP1, SP2, SP3, SP4 may be modified depending on the design of the first substrate 110 (or the second substrate 200). For example, the first to fourth sub-pixels SP1, SP2, SP3, SP4 may be disposed in a row in the first direction (Y-axis direction), and the transmissive portion TA may be disposed on one side of each of the first to fourth sub-pixels SP1, SP2, SP3, SP4.

Since the transparent display apparatus 100 according to an example embodiment of the present disclosure is configured that the light emitting element emits white light, thus the second sub-pixel SP2, which is a white sub-pixel as shown in FIG. 2, may not be provided with a color filter. On the other hand, the fourth sub-pixel SP4 may be provided with a blue color filter 210 (shown in FIG. 3) such that blue light is emitted, the first sub-pixel SP1 may be provided with a red color filter 211 (shown in FIG. 3) such that red light is emitted, and the third sub-pixel SP3 may be provided with a green color filter such that green light is emitted.

Hereinafter, with reference to FIGS. 2 and 3, the pixel P of a transparent display apparatus 100 according to an example embodiment of the present disclosure will be described.

Referring to FIGS. 2 and 3, each of the plurality of pixels P provided in the display area DA may include the plurality of sub-pixels SP and the transmission area TA. The transmissive portion TA may be disposed adjacent to each of the first sub-pixel SP1 and the second sub-pixel SP2, as shown in FIG. 2. In FIG. 3, a sub-pixel SP in which the dam area 120 and the buffer portion BP are disposed is illustrated, but the filling member RF may be disposed in the sub-pixel SP disposed in the display area DA rather than the dam area 120. However, as shown in FIG. 4, both the filling elements RF and the dam area 120 may not be disposed in the area where the space CP is disposed. The space CP may be a portion that is cut through a cutting device, such as a laser or wheel. For example, when the cutting device cuts the space CP, the transparent display apparatus 100 according to an example embodiment of the present disclosure may be divided into a first transparent display apparatus 101 and a second transparent display apparatus 102. In FIG. 1, the transparent display apparatus 100 according to an example embodiment of the present disclosure is shown configured to be divided into two transparent display apparatuses having the same area (or size), but it is not limited thereto and may be configured to be divided into two transparent display apparatuses having different areas (or sizes).

The space CP, according to one example, may be formed between the first sub-dam 1211a of the first dam 121 and the first sub-dam 1221a of the second dam 122. The area between the first sub-dam 1211a of the first dam 121 and the first sub-dam 1221a of the second dam 122 where the space CP is formed may be a cutting margin area CMA for cutting. As shown in FIG. 4, the cutting margin area CMA may be a space area, as both the filling member RF and the dam area 120 are not disposed in the CMA. In one example, the space area may be a vacuum. On the other hand, as shown in FIG. 4, since the cutting margin area CMA is a space area, the cutting margin area CMA may be connected to an undercut portion UC or a space CP of some of the plurality of undercut portions UC.

Accordingly, the transparent display apparatus 100 according to an example embodiment of the present disclosure may have a reduced manufacturing cost due to material savings, as both the filling member RF and the dam area 120 are not formed in the space CP (or the cutting margin area CMA), and may also have a reduced defect rate as the area in which the filling member RF and the dam area 120 are not disposed may be cut to facilitate cutting.

On the other hand, since the structure of the sub-pixel SP in which the filling member RF is disposed is the same as the structure of the sub-pixel SP in which the dam area 120 is disposed, as shown in FIG. 3, the description thereof will be replaced by the description of the sub-pixel SP in which the dam area 120 is disposed.

Referring again to FIG. 3, each of the plurality of sub-pixels SPs may be disposed on the first substrate 110 and may include a buffer layer BL to prevent or reduce moisture permeation to the thin film transistors 112.

Further, each of the sub-pixels SPs according to an example embodiment of the present disclosure comprises an inorganic layer 111, a planarization layer 113 provided on the inorganic layer 111, an anode electrode 114 (or first electrode 114) provided on the planarization layer 113, a bank 115, the organic emitting layer 116, a cathode electrode 117 (or second electrode 117), and an encapsulation layer 118. The inorganic layer 111 is provided on an upper surface of the buffer layer BL and includes a gate insulator 111a, an interlayer insulating layer 111b, a first passivation layer 111c, and a second passivation layer 111d.

The inorganic layer 111 may be disposed with thin-film transistors 112 for driving the sub-pixels SP. The inorganic layer 111 may also be expressed in terms of a circuit element layer. A buffer layer BL may be included in the inorganic layer 111 along the gate insulating layer 111a, the interlayer insulating layer 111b, the first passivation layer 111c, and the second passivation layer 111d. The anode electrode 114, the organic emitting layer 116, and the cathode electrode 117 may be included in the light emitting element.

The buffer layer BL may be formed between the first substrate 110 and the gate insulating layer 111a to protect the thin film transistor 112. Between the buffer layer BL and the first substrate 110, a pixel power line EVDD or a wiring electrically connected to the pixel power line EVDD may be disposed. The buffer layer BL may be disposed entirely on one surface (or front surface) of the first substrate 110. The buffer layer BL may serve to prevent or reduce a material contained in the first substrate 110 from being diffused into a transistor layer during a high temperature process of the manufacturing process of the thin film transistor. Optionally, the buffer layer BL may be omitted as the case may be.

The thin film transistor 112 according to an example may include an active layer 112a, a gate electrode 112b, a source electrode 112c, and a drain electrode 112d.

The active layer 112a may include a channel area, a drain area and a source area, which are formed in a thin film transistor area of a circuit area of the pixel P. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a, or may be formed on an entire front surface of the first substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. The interlayer insulating layer 111b may be formed in the circuit area and an entire light emission area, in which light is emitted to the pixel P. For example, the interlayer insulating layer 111b may be made of an inorganic material, but is not necessarily limited thereto.

The source electrode 112c may be electrically connected to the source area of the active layer 112a through a source contact hole provided in the interlayer insulating layer 111b overlapped with the source area of the active layer 112a. Further, the source electrode 112c may be connected to the wiring LS electrically connected to the pixel power line EVDD through contact holes provided in the interlayer insulating layer 111b and the buffer layer BL that do not overlap with the source area of the active layer 112a. The source electrode 112c may be connected to the anode electrode 114 via a connection electrode CE penetrating the first passivation layer 111c.

The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the pixel P to have the same structure as that of the thin film transistor 112, its description will be omitted. The capacitor may be provided in an overlap area between the gate electrode 112b and the source electrode 112c of the thin film transistor 112, which overlap each other with the interlayer insulating layer 111b interposed therebetween.

Additionally, in order to prevent or reduce a threshold voltage of the thin film transistor provided in a pixel area from being shifted by light, the display panel or the first substrate 110 may further include a light shielding layer (not shown) provided below the active layer 112a of at least one of the thin film transistor 112, the first switching thin film transistor or the second switching thin film transistor. The light shielding layer may be disposed between the first substrate 110 and the active layer 112a to shield light incident on the active layer 112a through the first substrate 110, thereby minimizing or reducing a change in the threshold voltage of the transistor due to external light. For example, if the wiring LS connected to the pixel power line is an opaque wiring, the wiring LS may also have the function of a light blocking layer.

The first passivation layer 111c may be disposed between the first substrate 110 and the planarization layer 113. The first passivation layer 111c, according to one example, covers a drain electrode 112d and the source electrode 112c of the thin film transistor 112 and the interlayer insulating layer 111b. The first passivation layer 111c may be formed throughout the circuit area and the light emission area.

The second passivation layer 111d may be provided on the first substrate 110 to cover the pixel (or the light emission area EA). For example, the second passivation layer 111d may be provided to cover the connection electrode CE between the first passivation layer 111c and the planarization layer 113. The first passivation layer 111c may be formed throughout the circuit area and the light emission area.

The planarization layer 113 may be provided on the first substrate 110 to cover the second passivation layer 111d. When the second passivation layer 111d is omitted, the planarization layer 113 may be provided on the first substrate 110 to cover the circuit area. The planarization layer 113 may be formed throughout the circuit area and the light emission area. Further, the planarization layer 113 may be formed throughout the display area DA and the non-display area NDA except for the pad area PA. For example, the planarization layer 113 may include an extension (or extensions) extending from the display area DA toward the rest of the non-display area NDA except for the pad area PA. Thus, the planarization layer 113 may have a relatively larger size than the display area DA.

The planarization layer 113 according to an example may be formed to be relatively thick, and thus may provide a flat surface on the display area DA and the non-display area NDA. For example, the planarization layer 113 may be made of an organic material such as photo acryl, benzocyclobutene, polyimide, and fluorine resin.

The anode electrodes 114 of the sub-pixels SP may be formed on the planarization layer 113. The anode electrode 114 is connected to the source electrode or the drain electrode of the thin film transistor 112 by being connected to the connection electrode CE through the contact hole through the planarization layer 113 and the second passivation layer 111d.

The anode electrode 114 may be made of at least one of a transparent metal material, a semi-transmissive metal material, or a metal material having high reflectance.

When the transparent display apparatus 100 is provided in a top emission mode, the anode electrode 114 may be formed of a metal material having high reflectance or a stacked structure of a metal material having high reflectance and a transparent metal material. For example, the anode electrode 114 may be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy may be an alloy such as silver (Ag), palladium (Pd), and copper (Cu).

When the transparent display apparatus 100 is provided in a bottom emission mode, the anode electrode 114 may be formed of a transparent conductive material (TCO) such as ITO and IZO, which may transmit light, or a semi-transmissive conductive material such as magnesium (Mg), silver (Ag) or an alloy of magnesium (Mg) and silver (Ag).

In addition, the material constituting the anode electrode 114 may include MoTi. The anode electrode 114 may be a first electrode or a pixel electrode.

The bank 115 is a non-light emission area in which light is not emitted, and may be provided to surround each of light emission areas of the plurality of subpixels SP. For example, the bank 115 may partition (or define) the respective light emission areas EA.

The bank 115 may be formed on the planarization layer 113 to cover an edge of the anode electrode 114, thereby partitioning (or defining) the light emission areas EA (or light emitting portions) of the plurality of subpixels SP.

The bank 115 may be formed to cover an edge of each of the anode electrodes 114 included in each of the sub-pixels SPs and to expose a portion of each of the anode electrodes 114. Accordingly, the bank 115 may cover an end of each of the anode electrodes 114, thereby preventing or reduce shorting of the anode electrodes 114 and the cathode electrodes 117. The exposed portion of the anode electrode 114 that is not covered by the bank 115 may be the light emission area EA (or the light emitting portion).

The bank 115 may be formed of an organic layer such as an acrylic resin, an epoxy resin, a phenolic resin, a polyamide resin, and a polyimide resin, but is not limited thereto.

The organic light emitting layer 116 is formed on the anode electrode 114 and the bank 115. When a voltage is applied to the anode electrode 114 and the cathode electrode 117, holes and electrons migrate to the organic emitting layer 116, respectively, and they combine with each other in the organic light emitting layer 116 to emit light.

The organic light emitting layer 116 may be formed of a plurality of subpixels SP and a common layer provided on the bank 115. In this case, the organic light emitting layer 116 may be provided in a tandem structure in which a plurality of light emitting layers, for example, a yellow-green light emitting layer and a blue light emitting layer are stacked, and may emit white light when an electric field is formed between the anode electrode 114 and the cathode electrode 117.

A color filter 210 suitable for a color of a corresponding subpixel SP may be formed on the second substrate 200. For example, a red color filter 211 may be provided in a red subpixel SP1, a green color filter may be provided in a green subpixel SP3, and a blue color filter 210 may be provided in a blue subpixel SP4. A white subpixel SP2 may not include a color filter because the organic light emitting layer 116 emits white light.

The cathode electrode 117 is formed on the organic light emitting layer 116. The cathode electrode 117 may be a common layer commonly formed in the subpixels SP. The cathode electrode 117 may be made of a transparent metal material, a semi-transmissive metal material or a metal material having high reflectance.

When the transparent display apparatus 100 is provided in a top emission mode, the cathode electrode 117 may be formed of a transparent conductive material (TCO) such as ITO and IZO, which may transmit light, or a semi-transmissive conductive material such as magnesium (Mg), silver (Ag) or an alloy of magnesium (Mg) and silver (Ag).

When the transparent display apparatus 100 is provided in a bottom emission mode, the cathode electrode 117 may be formed of a metal material having high reflectance, such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy of silver (Ag), palladium (Pd), copper (Cu), etc. The cathode electrode 117 may be a second electrode or an opposing electrode.

The encapsulation layer 118 is formed on the cathode electrode 117. The encapsulation layer 118 serves to prevent or reduce oxygen or water from being permeated into the organic light emitting layer 116 and the cathode electrode 117. To this end, the encapsulation layer 118 may include at least one organic layer and at least one inorganic layer.

In the transparent display apparatus 100 according to an example embodiment of the present disclosure, the encapsulation layer 118 may be disposed in the non-display area NDA as well as the display area DA. The encapsulation layer 118, according to one example, may be disposed between the cathode electrode 117 (and/or the buffer layer BL) and the second substrate 200.

Since the encapsulation layer 118 is disposed in the display area DA and extends into the non-display area NDA, the encapsulation layer 118 may contact the dam area 120 in the non-display area NDA (or on the periphery) of the display panel. Furthermore, since the transparent display apparatus 100 according to an example embodiment of the present disclosure includes the dam area 120 disposed in the display area DA and extending to a portion of the display area DA, the encapsulation layer 118 may be in contact with the dam area 120 (or the first dam 121 and the second dam 122) even in the display area DA.

Thus, the transparent display apparatus 100 according to an example embodiment of the present disclosure may be prevented or reduced from moisture permeation toward the display area DA, and even if it is divided into a plurality of pieces through the space CP, moisture permeation toward the display area DA may be effectively prevented or reduced.

Referring again to FIG. 3, the color filter (for example, a red color filter 211 and a blue color filter 210) and the black matrix 220 may be disposed between the encapsulation layer 118 and the second substrate 200. In one example, the color filter may be disposed correspondingly to each of a plurality of sub-pixels SPs (or a plurality of light emission areas EA) on the second substrate 200 (or the opposing substrate).

As described above, the white sub-pixel, for example, the second sub-pixel SP2, may not be provided with a color filter since the organic light emitting layer 116 emits white light. On the other hand, in the first sub-pixel SP1, which is a red sub-pixel, a red color filter 211 may be provided between the encapsulation layer 118 and the second substrate 200. Also, in the fourth sub-pixel SP4, which is a blue sub-pixel, a blue color filter 210 may be provided between the encapsulation layer 118 and the second substrate 200.

As shown in FIG. 3, the black matrix 220 may be disposed at the edge of the color filter 210 and 211. Thus, the black matrix 220 may prevent or reduce color mixing between the sub-pixels SPs. The black matrix 220 may comprise a black-based material and may be disposed in the non-emitting area NEA. In one example, the black matrix 220 may be formed on the second substrate 200 in at least partially overlap the bank 115, thereby reducing the cell gap between the organic light emitting layer 116 and the second substrate 200, thereby preventing or reducing mixing between sub-pixels.

On the other hand, the transparent display apparatus 100, according to an example embodiment of the present disclosure, may further include a plurality of upper organic layers 230 covering color filters of at least one subpixel SP of the plurality of subpixels. For example, as shown in FIG. 3, each of the plurality of upper organic layers 230 may be configured to cover the blue color filter 210 and the red color filter 211. Additionally, each of the plurality of upper organic layers 230 may be configured to cover a black matrix 220 disposed between the color filters. In FIG. 3, one upper organic layer 230 is shown covering two color filters 210, 211, but is not necessarily limited thereto, and one upper organic layer 230 may be configured to cover one color filter disposed on one sub-pixel SP.

In one example, the plurality of upper organic layers 230 may be spaced apart from each other interposed the transmissive portion TA (or a part of the transmissive portion (TA)) therebetween. Since the upper organic layer 230 is an organic layer, it may be a moisture permeable path from the outside to the display area DA. However, in the transparent display apparatus 100 according to an example embodiment of the present disclosure, the plurality of upper organic layers 230 may be spaced apart from each other, thus the moisture permeation path to the display area DA may be blocked.

Furthermore, the transparent display apparatus 100 according to an example embodiment of the present disclosure is configured such that the plurality of upper organic layers 230 are not disposed on a part or all of the transmissive portion TA, thus the transmittance may be improved as compared to the case where the organic layers are disposed in the transmissive portion TA.

In addition, the plurality of upper organic layers 230 are spaced apart from each other with the transmissive portion TA (or a portion of the transmissive portion TA) interposed therebetween, therefore the dam area 120 (or the first sub-dam 1211 and the second sub-dam 1212) may be disposed between the plurality of upper organic layers 230. For example, the dam area 120 may be partially disposed between the plurality of upper organic layers 230. The dam area 120 according to one example may be disposed entirely between the plurality of upper organic layers 230, as shown in FIG. 3. However, it is not limited thereto, the dam area 120 may be disposed only partially between the plurality of upper organic layers 230. This describes the arrangement structure of dam area 120, and in the display area DA where the dam area 120 is not disposed, the filling member RF may be disposed between the plurality of upper organic layers 230.

In the transparent display apparatus 100 according to an example embodiment of the present disclosure, the plurality of dam areas 120 may be provided in first to Nth (N is a natural number greater than one) numbers on the first substrate 110. For example, as shown in FIG. 1, the transparent display apparatus 100 according to an example embodiment of the present disclosure may include the first dam 121 and the second dam 122. As shown in FIG. 1, the first dam 121 and the second dam 122 may be configured in a closed loop shape (or closed form) surrounding portions of the display area DA having the same area, respectively. However, it is not limited thereto, the first dam 121 and the second dam 122 may be configured in a closed loop form (or closed form) surrounding the display area DA having the different areas, respectively.

The first dam 121 may include the first sub-dam 1211 extending from the non-display area NDA to the display area DA and surrounding a portion of the display area DA (e.g., the first display area DAI on the left side of FIG. 1), and the second sub-dam 1212 disposed spaced apart from one side of the first sub-dam 1211 inside the area surrounded by the first sub-dam 1211. As shown in FIG. 1, since the first sub-dam 1211 and the second sub-dam 1212 may be connected to each other, the buffer portion BP (or the first buffer portion BP1) may be provided between the first sub-dam 1211 and the second sub-dam 1212. As shown in FIG. 1, the second sub-dam 1212 is disposed inside the area surrounded by the first sub-dam 1211, thus the first sub-dam 1211 may be disposed closer to the space CP (shown in FIG. 1) than the second sub-dam 1212. The first sub-dam 1211 may include a first side 1211a, a second side 1211b, a third side 1211c, and a fourth side 1211d.

The second dam 122 may include the first sub-dam 1221 extending from the non-display area NDA to the display area DA and surrounding a portion of the display area DA (e.g., the second display area DA2 on the right side of FIG. 1), and the second sub-dam 1222 disposed to be spaced apart from one side of the first sub-dam 1221 inside the area surrounded by the first sub-dam 1221. As shown in FIG. 1, since the first sub-dam 1221 and the second sub-dam 1222 may be connected to each other, the buffer portion BP (or the second buffer portion BP2) may be provided between the first sub-dam 1221 and the second sub-dam 1222. As shown in FIG. 1, the second sub-dam 1222 of the second dam 122 is disposed inside the area surrounded by the first sub-dam 1221, thus the first sub-dam 1221 may be disposed closer to the space CP than the second sub-dam 1222. The first sub-dam 1221 may include a first side 1221a, a second side 1221b, a third side 1221c, and a fourth side 1221d.

The first side 1211a of the first sub-dam 1211 included in the first dam 121, and the first side 1221a of the first sub-dam 1221 included in the second dam 122 may be disposed adjacent to each other with the space CP interposed therebetween. The first side 1221a, second side 1221b, third side 1221c, and fourth side 1221d of the second dam 122 may have a structure that is, inverted in the left-right direction, for example, in the second direction (X-axis direction), thus may have the same arrangement structure as the first side 1211a, second side 1211b, third side 1211c, and fourth side 1211d of the first dam 121. Accordingly, the descriptions of the first side 1221a, second side 1221b, third side 1221c, and fourth side 1221d of the second dam 122 are replaced by the descriptions of the first side 1211a, second side 1211b, third side 1211c, and fourth side 1211d of the first dam 121.

Referring again to FIG. 1, the one side of the first sub-dam 1211 included in the first dam 121 may be a first side 1211a of the first sub-dam 1211. The second side 1211b is the one edge of the first side 1211a, for example, it may be connected to the upper edge of the first side 1211a. The third side 1211c is the other edge of the first side 1211a, for example, it may be connected to the lower edge of the first side 1211a. The third side 1211c may be spaced apart from the second side 1211b. In one example, the third side 1211c may be disposed parallel to the second side 1211b in the second direction (X-axis direction). The fourth side 1211d may be disposed parallel to the first side 1211a and may be connected to each of the second side 1211b and the third side 1211c. Thus, the first sub-dam 1211 may be configured as a closed loop.

In addition, the second sub-dam 1212 of the first dam 121 may be spaced apart from the first side 1211a of the first sub-dam 1211 and may be connected to each of the second side 1211b and the third side 1211c. Thus, as shown in FIG. 1, the first side 1211a, a portion of the second side 1211b, and a portion of the third side 1211c of the first sub-dam 1211, and the second sub-dam 1212 may be configured as a closed loop.

As shown in FIG. 1, the first side 1211a of the first sub-dam 1211 and the second sub-dam 1212 may be disposed across the display area DA in the first direction (Y-axis direction). Thus, the transparent display apparatus 100 according to an example embodiment of the present disclosure may have a structural feature in which the dam area 120 (or the first dam 121) overlaps in a third direction (Z-axis direction) with the pixels P (or sub-pixels SP) disposed in the display area DA.

Referring to FIGS. 1 and 2, the transparent display apparatus 100 according to an example embodiment of the present disclosure may further include a space CP provided between the first to Nth dam areas 120 (or the first dam 121 and the second dam 122). The space CP according to one example may be a portion that is cut by a cutting device, such as a laser or a wheel. Thus, when the cutting device cuts the space CP, the transparent display apparatus 100 according to an example embodiment of the present disclosure may be divided into a first transparent display apparatus 101 and a second transparent display apparatus 102. In FIG. 1, the transparent display apparatus 100 according to an example embodiment of the present disclosure configured to be divided into two transparent display apparatuses having the same area (or size) is shown, but it is not limited thereto and may be configured to be divided into two transparent display apparatuses having different areas (or sizes).

Referring to FIG. 1 as an example, the transparent display apparatus 100 according to an example embodiment of the present disclosure may be configured to be divided into a first transparent display apparatus 101 having a first area, and a second transparent display apparatus 102 having a second area equal to the first area via a space CP. Between the first transparent display apparatus 101 and the second transparent display apparatus 102, for example, in the area where the space CP is disposed (or the cutting margin acquisition area CMA), the filling member RF and the dam area 120 may not be disposed. Accordingly, the transparent display apparatus 100 according to an example embodiment of the present disclosure may have a reduced manufacturing cost as the filling member RF and the dam area 120 are not formed between the first transparent display apparatus 101 and the second transparent display apparatus 102, and may have a reduced defect rate since the cutting may be made easily as the cutting is made in an area where the filling member RF and the dam area 120 are not disposed.

Furthermore, the transparent display apparatus 100 according to an example embodiment of the present disclosure may be provided with the plurality of dam areas 120 in a number corresponding to the number of the plurality of gate drivers GD. Accordingly, the transparent display apparatus 100 according to an example embodiment of the present disclosure may be provided to be divided into a plurality of transparent display apparatuses as many as the number of the plurality of gate drivers GDs (or the number of the plurality of dam areas 120). For example, the first transparent display apparatus 101 may be driven by including a first gate driver GD1 on the left side of FIG. 1, and a second transparent display apparatus 102 may be driven by including a second gate driver GD2 on the right side of FIG. 1.

Referring again to FIG. 1, in the transparent display apparatus 100 according to an example embodiment of the present disclosure, each of the plurality of gate drivers GDs may be disposed long in the first direction (Y-axis direction) in the non-display area NDA. Here, the space CP may be disposed parallel to the gate driver GD. Because when the space CP is disposed in a direction that crosses the gate driver GD, the gate driver GD is damaged by the cutting device and may not be operated as a transparent display apparatus. Therefore, in the transparent display apparatus 100 according to an example embodiment of the present disclosure, the space CP may be disposed parallel to the gate driver GD. For example, as shown in FIG. 1, the space CP may be disposed long in the first direction (Y-axis direction) between the two gate drivers (the first gate driver GD1, the second gate driver GD2). Therefore, the transparent display apparatus 100 according to an example embodiment of the present disclosure may be cut in the first direction (Y-axis direction) by the cutting device, accordingly may be configured to be divided into a first transparent display apparatus 101 and a second transparent display apparatus 102 having different areas (or sizes).

As shown in FIG. 1, the space CP is disposed in a perpendicular direction and may therefore be expressed in terms of a perpendicular cutting line. Alternatively, the space CP may be expressed in terms of a one way cutting line, as the transparent display apparatus 100 is cut in one direction.

Referring again to FIG. 1, in the transparent display apparatus 100 according to an example embodiment of the present disclosure, the circuit board 150 may include a first circuit board 151, a second circuit board 152, a third circuit board 153, and a fourth circuit board 154. For example, the first circuit board 151 and the second circuit board 152 may be connected to the first transparent display apparatus 101. The first circuit board 151 and the second circuit board 152 may be connected to the timing controller via a cable. The third circuit board 153 and the fourth circuit board 154 may be connected to the second transparent display apparatus 102. The third circuit board 153 and the fourth circuit board 154 may be connected to the timing controller via a cable. Thus, when the transparent display apparatus 100 according to an example embodiment of the present disclosure is separated (or divided) by the cutting device, the first transparent display apparatus 101 and the second transparent display apparatus 102 may function as respective transparent display apparatuses having the same or different areas (or sizes).

The transparent display apparatus 100 according to an example embodiment of the present disclosure may include the planarization layer 113 disposed on the first substrate 110, and a plurality of inorganic layers 111 disposed between the first substrate 110 and the planarization layer 113. For example, the plurality of inorganic layers 111 may be the gate insulator 111a, the interlayer insulating layer 111b, the first passivation layer 111c, and the second passivation layer 111d disposed on the upper surface of the buffer layer BL.

The transparent display apparatus 100, according to an example embodiment of the present disclosure, may include an undercut portion UC from which the planarization layer 113 and the plurality of inorganic layers 111 have been partially removed.

The undercut portion UC according to one example may be formed by partially removing each of the interlayer insulating layer 111b, the first passivation layer 111c, and the second passivation layer 111d. As shown in FIG. 3, the undercut portion UC may be formed in the transmissive portion TA, for example, the transmissive portion TA may include the undercut portion UC.

The undercut portion UC is for disconnecting the organic light emitting layer 116 provided in the transmissive portion TA. Since in the transparent display apparatus 100 according to an example embodiment of the present disclosure, the organic light emitting layer 116, the cathode electrode 117, and the encapsulation layer 118 is formed after the undercut portion UC is formed, the organic light emitting layer 116 may be disconnected by the undercut portion UC. Thus, the transparent display apparatus 100 according to an example embodiment of the present disclosure may be prevented or reduced from moisture permeation through the organic light emitting layer 116.

The undercut portion UC according to one example may be provided in the transmissive portion TA with in first to Mth numbers (M being a natural number greater than zero). Since the undercut portion UC is an area in which the organic light emitting layer 116 is discontinuous, moisture permeation to the display area DA may be prevented or reduced even if the undercut portion UC is cut by a cutting device. Therefore, in the transparent display apparatus 100 according to an example embodiment of the present disclosure, the space CP may be any one of the first to Mth undercut portions UC. For example, as shown in FIG. 4, the undercut portions UC may be formed on both side of the planarization layer 113′ disposed on the transmissive portion TA. The planarization layer 113′ disposed in the transmissive area TA is disposed in the shape of an island spaced apart from the planarization layer 113 disposed in the light emission EA, and may therefore be expressed in terms of an island OC or first planarization layer. In contrast, the planarization layer 113 disposed to overlap the light emission area EA (and/or the non-light emission area NEA) is disposed to cover the thin-film transistor 112 thus may therefore be expressed in terms of a capping OC or second planarization layer.

For example, as shown in FIG. 2, two of the planarization layer 113′ (or first planarization layer 113′) disposed on the transmissive area TA may be in parallel to the first direction (Y-axis direction) on the transmissive area TA. In this case, one transmissive area TA may have four undercut portions UC disposed therein, as shown in FIG. 4. Any one of these four undercut portions UC may be the space CP. However, it is not necessary to be limited thereto, and the space CP may be formed in the light emission area EA or the transmissive area TA rather than in the undercut portions UC. Furthermore, the space CP may be disposed in an area that is not a dam area 120. But, the space CP may not be disposed in an area where the fill member RF is disposed. This is because in case that the space CP is disposed in the area where the filling member RF is disposed, moisture permeation may occur through the organic layer, such as the organic light emitting layer, when cut by the cutting device. Therefore, in the transparent display apparatus 100 according to an example embodiment of the present disclosure, the space CP may be disposed in at least one of the undercut portions UC in an area where the filling member RF is not disposed, the light emission area EA in an area where the filling member RF is not disposed, and the transmissive area TA in an area where the filling member RF is not disposed. Hereinafter, one of the plurality of undercuts UCs is described as the space CP.

The transparent display apparatus 100 according to an example embodiment of the present disclosure may be implemented as a plurality of transparent display apparatuses having different areas or the same area when any one of the first to M undercut portions UC is cut by a cutting device. Since the organic light-emitting layer 116 is discontinuous in the undercut portion UC, moisture permeation through the organic light-emitting layer 116 may be prevented or reduced even when cut by the cutting device. Furthermore, since the space CP is disposed between the plurality of dam areas 120 (or between the first dam 121 and the second dam 122), even if the space CP is cut by the cutting device, the edges of each transparent display apparatus (e.g., the first transparent display apparatus 101 and the second transparent display apparatus 102) may be provided with a structure in which the dam areas 120 surround the display area DA. Also, in each of the transparent display apparatuses (e.g., the first transparent display apparatus 101 and the second transparent display apparatus 102), the getter included in the dam areas 120 disposed at the edges may be capable of absorbing moisture and oxygen, thereby further maximizing, enhancing or increasing the prevention of moisture penetration to the display area DA.

Referring to FIG. 3, in the transparent display apparatus 100 according to an example embodiment of the present disclosure, the organic light emitting layer 116 may be discontinuous at the undercut portion UC. In addition, each of the cathode electrode 117 and the encapsulation layer 118 may also be discontinuous at the undercut portion UC. Thus, as shown in FIG. 3, the first planarization layer 113′, the organic light emitting layer 116 disposed on the first planarization layer 113′, the cathode electrode 117, and the encapsulation layer 118 may be disposed to be a shape of an island. Thus, undercuts UC may be formed on either side of the first planarization layer 113′, and the dam area 120 may be disposed up to the undercuts UC disposed on either side of the first planarization layer 113′. The transparent display apparatus 100 according to an example embodiment of the present disclosure may be further prevented or reduced from moisture permeation because the dam area 120 including getters are disposed up to the undercut portion UC. However, it is not necessary to be limited to this, and the dam area 120 may be partially formed only on one side of the first planarization layer 113′.

On the other hand, the transparent display apparatus 100 according to an example embodiment of the present disclosure may be formed the space so that various types (or various sizes) of the transparent display apparatus may be manufactured without an additional masking process through the process of forming the undercut portion UC that disconnects the organic emitting layer 116, thus production energy may be reduced compared to the case of manufacturing various types (or various sizes) of the transparent display apparatus through various processes.

In the transparent display apparatus 100 according to an example embodiment of the present disclosure, the buffer portion BP may be disposed to overlap the light emission area EA. For example, as shown in FIG. 3, the buffer portion BP may be disposed to overlap the light emission area EA of the first sub-pixel SP1 and the light emission area EA of the fourth sub-pixel SP4. Thus, the buffer portion BP stores outgassing emitted in the first emission direction D1 from the second sub-dam 1212 disposed on one side of the fourth sub-pixel SP4 (e.g., the left side of the fourth sub-pixel SP4 in FIG. 3), and outgassing emitted in the second emission direction D2 from the first sub-dam 1211 (or the first side 1211a) disposed on one side of the first sub-pixel SP1 (e.g., the right side of the first sub-pixel SP1 in FIG. 3).

On the other hand, in FIG. 3, the buffer portion BP of the transparent display apparatus 100 according to an example embodiment of the present disclosure is described as being disposed to overlap two light emission areas EA, but is not limited thereto, and the buffer portion BP may be disposed to overlap one light emission area EA. Alternatively, the buffer portion BP may be disposed to overlap with three or more light emission areas EAs if moisture permeation may be prevented or reduced. As a result, in the transparent display apparatus 100 according to an example embodiment of the present disclosure, the buffer portion BP may be disposed to overlap one or more light emission areas EA.

The buffer portion BP according to one example may overlap a portion of the light emission area EA, a non-light emission area NEA adjacent to the light emission area EA, and the transmissive portion TA adjacent to the non-light emission area NEA, depending on where the dam area 120 is formed, as shown in FIG. 3.

As shown in FIG. 3, the dam area 120 (or the first sub-dam 1211 and the second sub-dam 1212) may be blocked from flow by at least one undercut portion UC of the plurality of undercut portions UC. Accordingly, the transparent display apparatus 100 according to an example embodiment of the present disclosure may include a structural feature in which the buffer portion BP is disposed along the undercut portion UC.

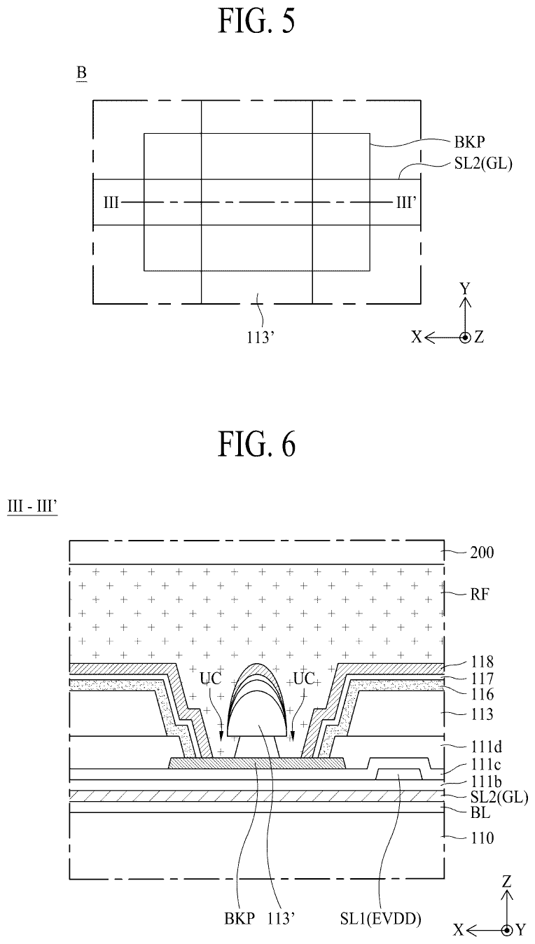

FIG. 5 is an enlarged plan view of portion B shown in FIG. 2, and FIG. 6 is a schematic cross-sectional view of line III-III′ shown in FIG. 5.

Referring to FIGS. 5 and 6, in the transparent display apparatus 100 according to an example embodiment of the present disclosure, the undercut portion UC may include a blocking portion BKP that partially overlaps the planarization layer 113′ (or the first planarization layer 113′) between the first passivation layer 111c and the second passivation layer 111d. For example, the blocking portion BKP may be formed at an intersection of the first planarization layer 113′ and the second line SL2 (or gate line GL), as shown in FIG. 5.

The blocking portion BKP is to prevent or reduce all of inorganic layers disposed on upper of the wiring (e.g., the second line SL2 (or gate line GL)) from being etched by the etchant used when the undercut portion UC is formed. Therefore, as shown in FIG. 6, the blocking portion BKP is disposed on inorganic layer (or the interlayer insulating layer 111b and the first passivation layer 111c) on the second line SL2 (or the gate line GL) thus inorganic layer (or the interlayer insulating layer 111b and the first passivation layer 111c) is protected from the etching solution. Accordingly, contact between the second line SL2 (or gate line GL) and the cathode electrode 117 may be prevented or reduced when the cathode electrode 117 is deposited. The blocking portion BKP according to one example may comprise a metallic material with high resistance to the etchant. The blocking portion BKP may be formed in the same layer as the connecting electrode CE.

Referring to FIG. 6, the blocking portion BKP may be provided to have a wider width than the undercut portion UC in the second direction (X-axis direction). Thus, the edge of the blocking portion BKP may be covered by the second passivation layer 111d. The organic light emitting layer 116 and the cathode electrode 117 and the encapsulation layer 118, respectively, cut off by the undercut portion UC, may be contacted on the upper surface of the blocking portion BKP.

On the other hand, as shown in FIG. 6, the filling member RF used for bonding the first substrate 110 and the second substrate 200 may be disposed on the upper side of the encapsulation layer 118 and the upper side of the blocking portion BKP. This is because the fill member RF is disposed on the display area DA (the first display area DA1 or the second display area DA2) surrounded by the dam area 120 (the first dam 121 or the second dam 122).

As a result, the transparent display apparatus 100 according to an example embodiment of the present disclosure is configured to include the blocking portion BKP that partially overlaps the undercut portion UC, which may protect at least a portion of the inorganic film layer disposed on upper of the wiring from the etchant used when the undercut portion UC is formed, thereby preventing or reducing contact of the second line SL2 (or gate line GL) with the cathode electrode 117.

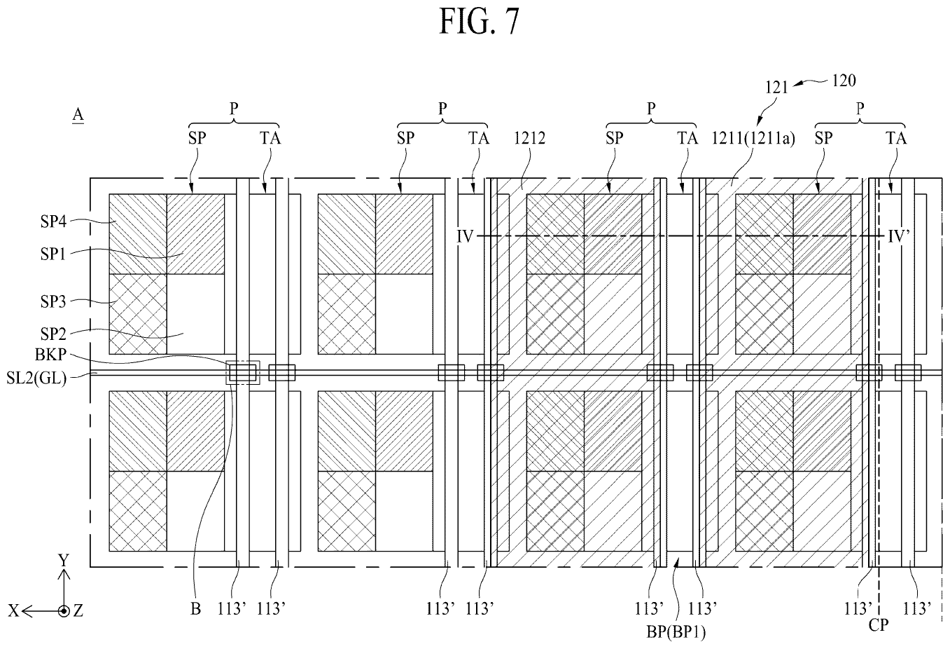

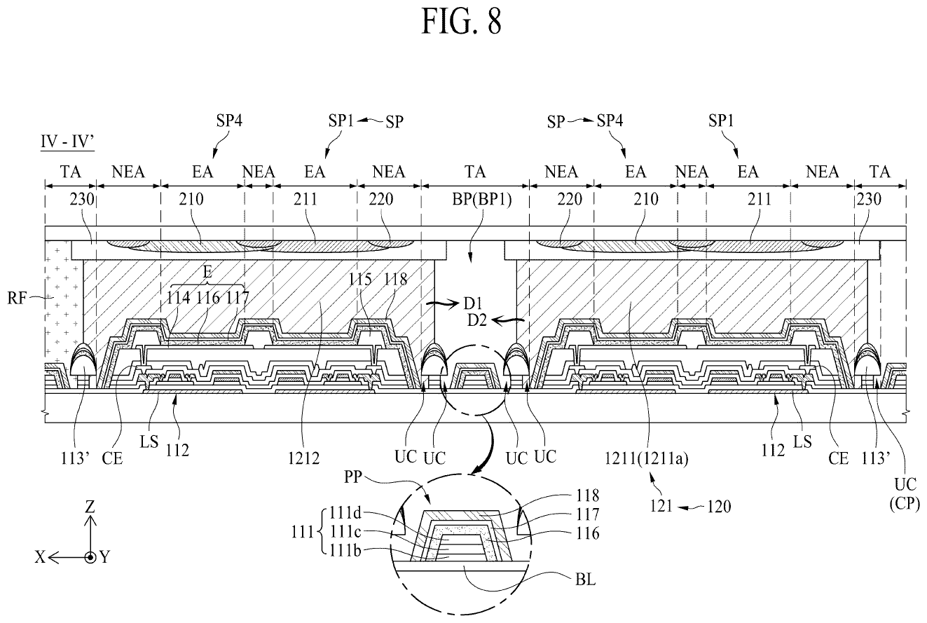

FIG. 7 is a schematic plan view of a transparent display apparatus according to another embodiment of the present disclosure, and FIG. 8 is a schematic cross-sectional view of lines IV-IV′ shown in FIG. 7.

Referring to FIG. 7, the transparent display apparatus 100 according to another embodiment of the present disclosure is identical to the transparent display apparatus according to FIG. 1 described above, except that the position where the buffer portion BP is disposed has been changed. Therefore, the same drawing symbols have been assigned to the same configuration, and only the different configurations will be described hereinafter.

In the case of the transparent display apparatus according to FIG. 1 described above, since the buffer portion BP is disposed to overlap the light emission area EA, outgassing contained in the dam area 120 (or the first sub-dam 1211 or 1221 and the second sub-dam 1212 or 1222) adjacent to the light emission area EA can be released (or stored) into the buffer portion BP formed on the light emission area EA (or the buffer portion BP containing the light emission area EA). Thus, in the case of the transparent display apparatus according to FIG. 1, the out gassing emitted from the dam area 120 (or the first sub-dam 1211 or 1221 and the second sub-dam 1212 or 1222) may not penetrate into the organic light emitting layer 116 and may be released into the buffer portion BP, thereby preventing or reducing the pixels P (or sub-pixels SP) from the occurrence of dark spots by the outgassing emitted from the dam area 120.

In contrast, in the case of the transparent display apparatus according to FIG. 7, the buffer portion BP may be disposed to overlap at least a portion of the transmissive portion TA. For example, as shown in FIG. 8, the buffer portion BP may be disposed to overlap a portion of the transmissive portion TA that is between the light emission area EA (or the non-light emission area NEA) of the first sub-pixel SP1 and the light emission area EA (or the non-light emission area NEA) of the fourth sub-pixel SP4. As shown in FIG. 8, organic layers (e.g., the planarization layer 113 and the upper organic layer 230) may be hardly disposed on the transmissive portion TA compared to the light emission area EA. Thus, in the case of the transparent display apparatus according to FIG. 7, the buffer portion BP may be provided to be disposed in the transmissive portion TA where there is less (or minimized) organic film on the first substrate 110 and the second substrate 200 compared to the light emission area EA, thereby further preventing or reducing the outgassing of the dam area 120 from penetrating through the organic film into the organic light emitting layer 116.

In addition, referring to FIG. 8, in the transparent display apparatus 100 according to FIG. 7, the transmissive portion TA may include a patterned portion PP formed by partially removing a plurality of inorganic film layers 111, organic light emitting layers 116, cathode electrodes 117, and the encapsulation layer 118. In the case of the transparent display apparatus according to FIG. 7, the buffer portion BP is disposed to overlap on the transmissive portion TA (or a portion of the transmissive portion TA), thus the buffer portion BP may also include the patterned portion PP. As shown in FIG. 8, the patterned portion PP according to an example may be disposed in an island shape, as the undercut portions UC formed in the transmissive portion TA are disposed on the left and right sides of the transmissive portion TA.

More specifically, as the undercut portions UC are disposed on either side of the patterned portion PP, the plurality of inorganic film layers 111 included in the patterned portion PP (e.g., an interlayer insulating layer 111b, the first passivation layer 111c, the second passivation layer 111d) may be discontinuous with the plurality of inorganic film layers 111 in the light emission area EA (or the non-light emission area NEA), and the discontinuous plurality of inorganic film layers 111 disposed in the transmission area TA may be covered by the organic light emitting layer 116. In this case, both ends of the organic light-emitting layer 116 may be in contact with the upper surface of the buffer layer BL, respectively. Then, the organic light-emitting layer 116 may be covered by the cathode electrode 117, and the cathode electrode 117 may be covered by the encapsulation layer 118. In this case, each of the two ends of the cathode electrode 117 and each of the two ends of the encapsulation layer 118 may be in contact with the upper surface of the buffer layer BL. Thus, the patterned portion PP disposed in the transmissive portion TA includes a plurality of isolated inorganic film layers 111 and isolated organic light emitting layers 116, isolated cathode electrodes 117 and isolated encapsulation layers 118, and may be disposed in an island shape. The encapsulation layer 118 includes at least one inorganic film, therefore outgassing emitted into the transmissive portion TA may be prevented or reduced from penetrating into the isolated organic light emitting layer 116 (or the island-shaped organic light emitting layer 116). Thus, the transparent display apparatus 100 according to other embodiments of the present disclosure may prevent or reduce the pixels P (or sub-pixels SP) from the occurrence of dark spots due to outgassing in the dam area 120 even when the buffer portion BP overlaps at least a portion of the transmissive portion TA.

Furthermore, the transparent display apparatus 100 according to other embodiments of the present disclosure may be disposed such that the buffer portion BP, which is a vacuum, overlaps at least a portion of the transmissive portion TA, thereby improving the transmissivity compared to when the buffer portion BP is disposed to overlap the light emission area EA.

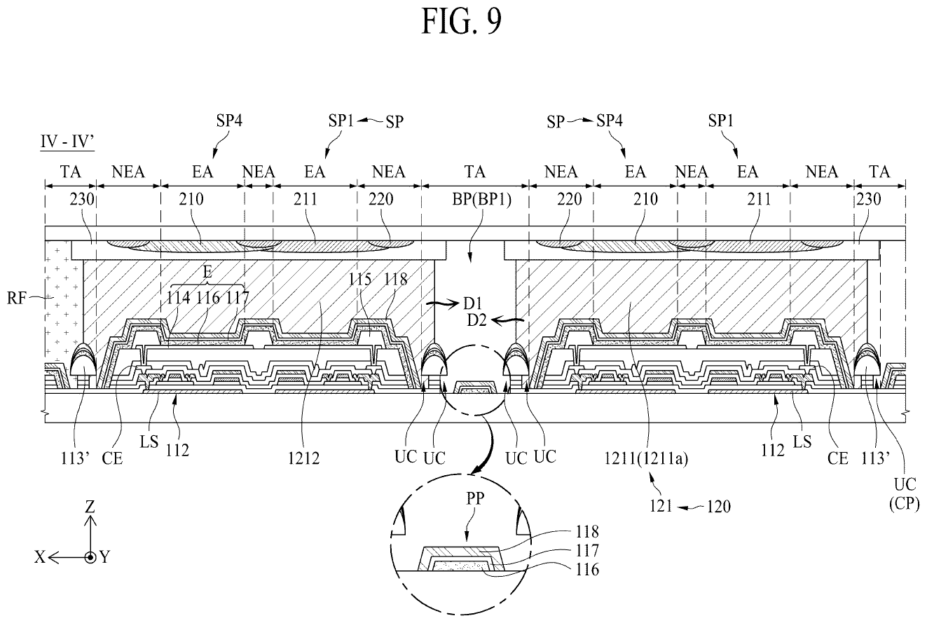

FIG. 9 is a cross-sectional view of the lines IV-IV′ shown in FIG. 7, illustrating a transparent display apparatus according to another embodiment of the present disclosure.

Referring now to FIG. 9, the transparent display apparatus 100 according to another embodiment of the present disclosure is identical to the transparent display apparatus according to FIG. 8 above, except that the structure of the pattern portion PP has been changed. Therefore, the same drawing symbols have been assigned to the same configuration, and only the different configuration will be described hereinafter.

In the case of the transparent display apparatus according to FIG. 8 described above, the buffer portion BP is disposed to overlap at least a portion of the transmissive portion TA, and the patterned portion PP of the buffer portion BP includes the plurality of isolated inorganic film layers 111, the isolated organic light emitting layers 116, the isolated cathode electrodes 117, and the isolated encapsulation layers 118, and may be disposed in an island shape. Thus, in the case of the transparent display apparatus according to FIG. 8, the outgassing of the dam area 120 may be emitted or stored in the buffer portion BP only, even though the buffer portion BP overlaps at least a portion of the transmissive portion TA, since the outgassing released or stored in the buffer portion BP is not able to penetrate into the organic light emitting layer 116 in the transmissive portion TA or the organic light emitting layer 116 in the light emission area EA (or non-light emission area NEA), preventing or reducing the pixels P (or sub-pixels SP) from the occurrence of dark spots by the outgassing emitted from the dam area 120.

In contrast, in the case of the transparent display apparatus according to FIG. 9, the buffer portion BP may include the patterned portion PP formed by partially removing the organic light emitting layer 116, the cathode electrode 117, and the encapsulation layer 118. In other words, the transparent display apparatus according to FIG. 9 may have a structure in which the plurality of inorganic film layers 111 (or the isolated inorganic film layers 111) that the patterned portion PP of the transparent display apparatus according to FIG. 8 includes are omitted. Accordingly, the transparent display apparatus 100 according to FIG. 9 may be formed with a thinner thickness of the patterned portion PP compared to the transparent display apparatus according to FIG. 8.

Furthermore, in the case of the transparent display apparatus 100 according to FIG. 9, the buffer layer BL under the patterned portion PP of the transparent display apparatus according to FIG. 8 may also be patterned and removed. Therefore, the transparent display apparatus 100 according to another embodiment of the present disclosure has a structure in which the thickness of the patterned portion PP in the transmissive portion TA in which the buffer portion BP is disposed is thinner than in the transparent display apparatus according to FIG. 8, and the buffer layer BL below the patterned portion PP is also removed, so that the space of the buffer portion BP may be wider than in the transparent display apparatus according to FIG. 8. Therefore, the transparent display apparatus 100 according to another embodiment of the present disclosure may allow the buffer portion BP to accommodate (or store) more of the outgassing emitted from the dam area 120. Furthermore, the transparent display apparatus 100 according to another embodiment of the present disclosure has a structure in which the patterned portion PP does not include a plurality of inorganic film layers 111, and the buffer layer BL below the patterned portion PP is also omitted (or deleted), so that the improvement of the transmittance of the transmissive portion TA may be further maximized, enhanced or increased compared to the transparent display apparatus according to FIG. 8.

On the other hand, the transparent display apparatus 100 according to an example embodiment of the present disclosure may be divided into a first transparent display apparatus 101 and a second transparent display apparatus 102 when the space CP is cut by a cutting device. Then, the first transparent display apparatus 101 may include the substrate 110 having the display area DA and the non-display area NDA (or bezel area), the dam area 120 (or the first dam 121) surrounding the display area DA on the substrate 110, and the buffer portion BP (or the first buffer portion BP1) disposed inside the area surrounded by the dam area 120 (or the first dam 121). In the display area DA, the plurality of pixels P having the plurality of sub-pixels SP and the transmissive portion TA, respectively, are disposed, and the non-display area NDA (or bezel area) is disposed around the display area DA. Further, the second transparent display apparatus 102 may include the substrate 110 having the display area DA and the non-display area NDA (or bezel area), the dam area 120 (or the second dam 122) surrounding the display area DA on the substrate 110, and the buffer portion BP (or the second buffer portion BP2) disposed inside the area surrounded by the dam area 120 (or the first dam 122). In the display area DA, the plurality of pixels P having the plurality of sub-pixels SP and the transmissive portion TA, respectively, are disposed and the non-display area NDA (or bezel area) is disposed around the display area DA.

The dam area 120 (or the first dam 121) included in the first transparent display apparatus 101 (or the first dam 121) and the buffer portion BP (or the first buffer portion BP1), and the dam area 120 (or the second dam 122) and the buffer portion BP (or the second buffer portion BP2) included in the second transparent display apparatus 102, respectively, are the same as the dam area 120 and the buffer portion BP included in the transparent display apparatus 100 described above, and therefore, a specific description thereof will be omitted.

As a result, the transparent display apparatus 100 according to an example embodiment of the present disclosure, with the space CP provided between the plurality of dam areas 120, may have reduced production energy compared to a transparent display apparatus produced in multiple varieties (or different sizes) through various production processes (or manufacturing processes).

Furthermore, even though the transparent display apparatus 100 according to an example embodiment of the present disclosure is divided into first and second transparent display apparatuses 101, 102, moisture permeation may be reduced or prevented because the plurality of dam areas 120 (or the first dam 121 and the second dam 122) cover the edges of each of the first and second transparent display apparatuses 101, 102 with a closed-loop structure (or closed structure).

Furthermore, the transparent display apparatus 100 according to an example embodiment of the present disclosure includes the buffer portion BP between the first sub-dam 1211 (or the first sub-dam 1221) and the second sub-dam 1212 (or the second sub-dam 1222), outgassing emitted from the first sub-dam 1211 (or the first sub-dam 1221) and/or the second sub-dam 1212 (or the second sub-dam 1222) may be induced and released into the buffer portion BP, so that damage to the organic light emitting layer may be prevented or reduced and dark spot occurrence may be prevented or reduced.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The claims are not limited by the disclosure.

The transparent display apparatus of the present disclosure includes the plurality of dam areas (or the first dam area and the second dam area) such that the display panel may be cut into various sizes.

Furthermore, the transparent display apparatus of the present disclosure may be manufactured in multiple varieties (or different sizes) without additional masking processes, which may result in lower production energy compared to transparent display apparatus produced in multiple varieties through different production processes.

Furthermore, the transparent display apparatus of the present disclosure is provided in such a way that the moisture permeation path in the cut portion is interrupted, so that moisture permeation may be reduced or prevented even when the product is manufactured in multiple varieties (or different sizes).

Further, the transparent display apparatus of the present disclosure provides the buffer portion between the first sub-dam and the second sub-dam adjacent to the cut portion, such that outgassing emitted from the first sub-dam and/or the second sub-dam may be stored in the buffer portion, thereby preventing or reducing the occurrence of dark spots.

The effects that may be obtained from the present disclosure are not limited to those mentioned above, and other effects not mentioned will be apparent to one having ordinary skill in the art from the following description.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent display apparatus comprising:
a substrate including a display area and a non-display area adjacent to the display area;
a plurality of pixels in the display area, the plurality of pixels each having a transmissive portion and a plurality of sub-pixels; and
a plurality of dams disposed on the substrate, wherein the plurality of dams comprises:
a first sub-dam surrounding a portion of the display area, and
a second sub-dam disposed on the display area and connected to a first side of the first sub-dam.

2. The transparent display apparatus of claim 1, wherein the plurality of dams are provided in first to Nth dam areas on the substrate, N being a natural number greater than one, and
the transparent display apparatus further comprises:
a space provided between the first dam areas to Nth dam areas.

3. The transparent display apparatus of claim 2, wherein the first sub-dam is disposed closer to the space than the second sub-dam.

4. The transparent display apparatus of claim 1, wherein the first sub-dam comprises a second side connected to a first edge of the first side, and a third side connected to a second edge of the first side and spaced apart from the second side, and
wherein the second sub-dam is connected to the second side and the third side, respectively.

5. The transparent display apparatus of claim 4, wherein the first side, a portion of the second side, and a portion of the third side of the first sub-dam and the second sub-dam is a closed loop.

6. The transparent display apparatus of claim 1, further comprising:
a buffer portion disposed between the first sub-dam and the second sub-dam.

7. The transparent display apparatus of claim 6, wherein the buffer portion is a vacuum.

8. The transparent display apparatus of claim 6, wherein each of the plurality of the sub-pixels comprise a light emission area disposed adjacent to the transmissive portion, and
wherein the buffer portion is disposed to overlap the light emission area.

9. The transparent display apparatus of claim 6, further comprising:
a planarization layer disposed on the substrate; and
a plurality of inorganic film layers disposed between the substrate and the planarization layer,
wherein the transmissive portion comprises an undercut portion where the planarization layer and the plurality of inorganic film layers are partially removed, and
wherein the buffer portion is disposed along the undercut portion.

10. The transparent display apparatus of claim 9, wherein the undercut portion is one of a plurality of undercut portions provided in first to Mth undercut portions in the transmissive portion, M being a natural number greater than zero.

11. The transparent display apparatus of claim 10, further comprising:
a space provided between the plurality of dams,
wherein the space is one of the plurality of undercut portions.

12. The transparent display apparatus of claim 9, wherein the plurality of inorganic film layers comprise:
a first passivation layer disposed between the substrate and the planarization layer; and
a second passivation layer disposed between the first passivation layer and the planarization layer, and
wherein the undercut portion comprises a blocking portion partially overlapping the planarization layer between the first passivation layer and the second passivation layer.

13. The transparent display apparatus of claim 12, wherein the substrate further comprises a gate line extended in one direction in the display area, and
wherein the blocking portion is disposed on the gate line.

14. The transparent display apparatus of claim 1, further comprising:
an opposing substrate disposed to face the substrate, the opposing substrate including a plurality of sub-pixels;
a color filter disposed to correspond to each of the plurality of sub-pixels on the opposing substrate; and
a plurality of upper organic layers covering the color filter of at least one sub-pixel among the plurality of the sub-pixels of the opposing substrate,
wherein the plurality of upper organic layer are disposed to be spaced apart from each other with the transmissive portion interposed therebetween.

15. The transparent display apparatus of claim 14, further comprising a filling member adjacent to dam areas corresponding to the plurality of dams, the filling member disposed to fill a gap between the substrate and the opposing substrate.

16. The transparent display apparatus of claim 1, wherein each of the first sub-dam and the second sub-dam includes an absorbent material.

17. The transparent display apparatus of claim 9, wherein each of the plurality of pixels comprises:
an anode electrode disposed on the planarization layer;
an organic light emitting layer disposed on the anode electrode;
a cathode electrode disposed on the organic light emitting layer; and
an encapsulation layer disposed on the cathode electrode, and
wherein the organic light emitting layer is discontinuous at the undercut portion.

18. The transparent display apparatus of claim 6, wherein the buffer portion is disposed to overlap at least a portion of the transmissive portion.

19. The transparent display apparatus of claim 18, wherein each of the plurality of pixels comprises:
a plurality of inorganic film layers disposed on the substrate;
an organic light emitting layer disposed on the plurality of the inorganic film layers;
a cathode electrode disposed on the organic light emitting layer; and
an encapsulation layer on the cathode electrode, and
wherein the buffer portion comprises a pattern portion in which the plurality of inorganic film layers, the organic light emitting layer, the cathode electrode and the encapsulation layer are partially removed.

20. The transparent display apparatus of claim 18, wherein each of the plurality of pixels comprises:
an organic light emitting layer disposed on the substrate;
a cathode electrode disposed on the organic light emitting layer; and
an encapsulation layer disposed on the cathode electrode, and
wherein the buffer portion comprises a pattern portion in which the organic light emitting layer, the cathode electrode and the encapsulation layer are partially removed.

21. The transparent display apparatus of claim 18, wherein each of the plurality of pixels comprises:
a buffer layer disposed on the substrate;
an organic light emitting layer disposed over the buffer layer;
a cathode electrode disposed on the organic light emitting layer; and
an encapsulation layer disposed on the cathode electrode, and
wherein the buffer portion comprises a pattern portion in which the buffer layer, the organic light emitting layer, the cathode electrode and the encapsulation layer are partially removed.

22. A transparent display apparatus comprising:
a substrate including a display area and a non-display area adjacent to the display area;
a plurality of pixels disposed in the display area, the plurality of pixels each having a transmissive portion and a plurality of sub-pixels;
a plurality of dams surrounding the display area; and
a buffer portion disposed inside an area of the substrate surrounded by the dams.

23. The transparent display apparatus of claim 22, wherein the dams comprise:
a first sub-dam surrounding the display area; and
a second sub-dam disposed to be spaced apart from a first side of the first sub-dam inside an area of the display area surrounded by the first sub-dam, and
wherein the buffer portion is disposed between the first sub-dam and the second sub-dam.

24. The transparent display apparatus of claim 22, wherein each of the plurality of the sub-pixels comprise a light emission area disposed adjacent to the transmissive portion, and
wherein the buffer portion is disposed to overlap the light emission area.

25. The transparent display apparatus of claim 22, wherein the buffer portion is disposed to overlap at least a portion of the transmissive portion.

26. The transparent display apparatus of claim 22, further comprising:
a planarization layer disposed on the substrate; and
a plurality of inorganic film layers disposed between the substrate and the planarization layer,
wherein the transmissive portion comprises an undercut portion where the planarization layer and the plurality of inorganic film layers are partially removed, and
wherein the buffer portion is disposed along the undercut portion.

27. A transparent display apparatus comprising:
a substrate including a display area having a plurality of pixels and a non-display area adjacent to the display area, the plurality of pixels each having a transmissive portion;
a plurality of dam areas disposed on the substrate; and
a cutting margin area provided between the plurality of dam areas.

28. The transparent display apparatus of claim 27, wherein the cutting margin area is a vacuum.

29. A transparent display apparatus comprising:
a substrate including a display area having a plurality of pixels and a non-display area adjacent to the display area, the plurality of pixels each having a transmissive portion;
a plurality of dam areas disposed on the substrate;
a gate line extending in a direction in the display area;
an undercut portion disposed in the transmissive portion; and
a blocking portion at an intersection of the undercut portion and the gate line.
